(19) United States
(12) Patent Application Publication
(10) Pub. No.: US 2006/0066388 A1
(43) Pub. Date: Mar. 30, 2006

(54) System and method for applying within-die adaptive body bias

(75) Inventors: James W. Tschanz, Portland, OR (US); Stephen H. Tang, Pleasanton, CA (US); Siva G. Narendra, Portland, OR (US); Vivek K. De, Beaverton, OR (US)

Correspondence Address: FLESHNER & KIM, LLP, P.O. BOX 221200, CHANTILLY, VA, 20153, US

(73) Assignee: Intel Corporation

(21) Appl. No.: 10/953,865

(22) Filed: Sep. 30, 2004

(51) Int. Cl. H03K 3/01

(52) U.S. Cl. 327/534

(57) ABSTRACT

A controller for providing within-die body bias includes a signal generator for generating different bias signals and a selector to route the bias signals to one or more specific types of transistors within the sections of the die. The controller may further include a plurality of secondary body bias generators, each disposed in a respective one of the die sections for translating the signals from the generator into local bias values. Through this controller, adaptive body bias techniques may be implemented which improve the bin split and overall performance of fabricated processors or other types of circuits formed on the die.

### BACKGROUND OF THE INVENTION

1. Field of the Invention

This invention relates to biasing one or more regions of an integrated circuit.

2. Description of the Related Art

Adaptive body bias is the dynamic adjustment of body bias on circuit elements (such as transistors) based on one or more performance considerations. This technique has been used to compensate for process variations in microprocessors and other semiconductor devices.

One proposed compensation method involves applying body bias values to different processor dies depending on the particular characteristics of each die. More specifically, after fabrication, the maximum operating frequency (F_{MAX}) and standby leakage current (I_{SB}) of each die is measured. Because of process variations (e.g., inconsistent channel lengths, doping levels, etc.), some dies may have a comparatively low maximum operating frequency and standby leakage current, while others may have high I_{SB} values which exceed a maximum leakage current constraint.

To compensate for process variations between dies, forward body bias has been applied to the slow dies to increase their F_{MAX} values and reverse body bias has been applied the leaky dies to reduce their I_{SB} values to levels which satisfy the leakage constraint. Because each processor die receives the same bias value, the proposed method compensates for die-to-die process variations. However, this method cannot account for within-die process variations, e.g., because within-die process variations result from differences in transistor characteristics across the same die, these variations cannot be compensated for through application of a single body bias voltage.

### BRIEF DESCRIPTION OF THE DRAWINGS

FIG. 1 is a diagram showing a controller for providing within-die body biasing in accordance with one embodiment of the present invention.

FIG. 2 is a diagram showing an example of how a central bias generator and selector of the controller may be constructed in accordance with one embodiment of the present invention.

FIG. 3 is a flow chart showing functional blocks that may be included in a method for providing within-die bias of a semiconductor device in accordance with one embodiment of the present invention.

FIG. 4 is a diagram showing a processing system that includes a controller in accordance with one or more of the embodiments of the present invention.

### DESCRIPTION OF THE PREFERRED EMBODIMENTS

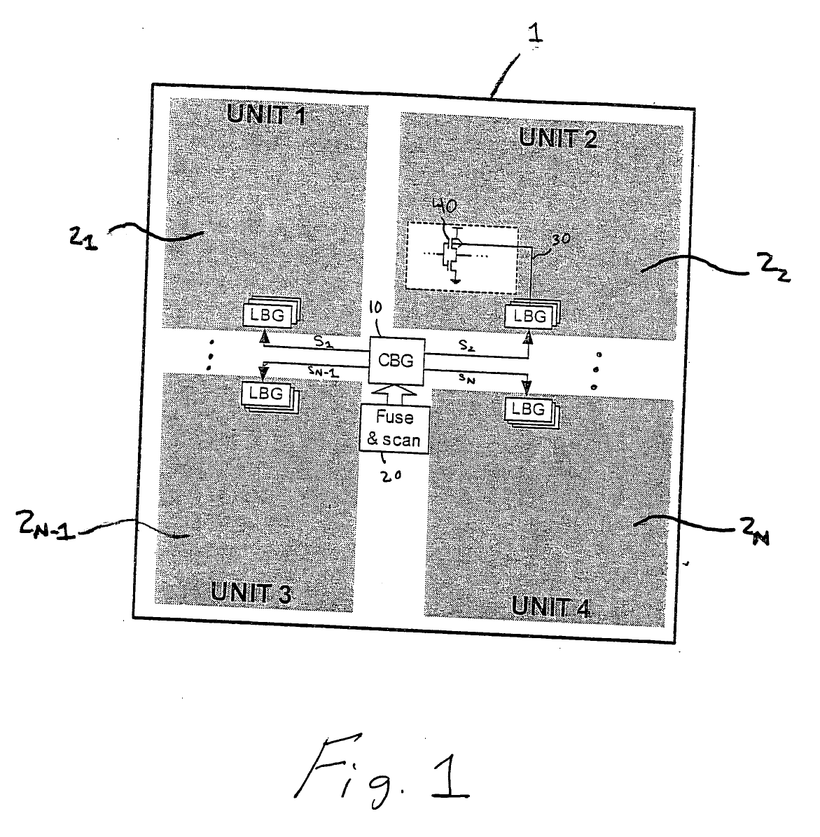

FIG. 1 shows a controller in accordance with a preferred embodiment of the present invention. The controller is formed on a semiconductor die 1 containing a plurality of sections (or units) 2₁, 2₂, . . . 2_{N-1}, 2_{N}. The sections are disposed on different areas of the die and preferably but not necessarily perform different functions within the host circuit. For illustrative purposes, four sections are shown. However, it is noted that the number of sections may be two or greater depending on, for example, within-die process variations, die size, application requirements and/or other considerations, e.g., large dies may require more sections because within-die variations are expected to be larger.

Each of the sections may further represent complete functional units within the host circuit, or they may be selected or defined based on other factors such as size, die location, host circuit type, etc. If the host circuit is a microprocessor, the units may include, for example, any one or more of an execution unit, bus unit, arithmetic logic unit, and cache. Other host circuits (e.g., ASICs, memories or memory controllers, interfaces, chipsets, graphics processors, digital signal processors, communications devices) may include different units selected based on function, area, or other grounds. When based on die location, each section may include portions of different functional units.

In the preferred embodiment the controller includes a central bias generator 10 and a selector 20, both of which are preferably formed on the die. The central bias generator generates a plurality of body bias signals S₁, S₂, . . . S_{N-1}, S_{N} which may be equal or different in number to the number of sections (or units) on the circuit. For example, if the body bias for each section is required to be different to meet the given requirements of a particular application, then the central bias generator preferably generates a different body bias signal for each section. On the other hand, if the body bias is the same or even similar for two or more sections, the same body bias signal may be generated for these sections.

In accordance with the present embodiment, the body bias signals are generated to bias transistors of a specific type in each section of the die. For example, the body bias signals may be applied to bias the PMOS transistors in each section of the die, without biasing any other type of transistor (e.g., NMOS transistors) in those sections. This may be accomplished, for example, because PMOS transistors are isolated from one another by virtue of being formed in separate N-wells within the die.

Alternatively, the body bias signals may be applied to bias the NMOS transistors in each section of the die, without biasing any other type of transistor (e.g., PMOS transistors) in those sections. This may be accomplished when, for example, the NMOS transistors are formed in the die using a triple-well process.

Restricting application of the body bias signals to transistors of a specific type may be accomplished by building conduction paths which lead only to transistor of that type. This is illustratively shown in FIG. 1, where conduction path 30 carries body bias signal S₂ to only PMOS transistors 40 in that section. (While only one PMOS is shown, it is understood that Unit 2 may include multiple transistors of this type). Similar paths may be formed between the central bias generator and transistors of the same type in the other sections. In implementing these features, it is noted that while the transistor type is restricted to receive the bias signals, other circuit elements that require biasing (e.g., diodes, capacitors, etc.) may not be restricted from receiving the bias signals.

The body bias signals are preferably generated to compensate for (e.g., reduce or eliminate) the within-die process variations in respective sections of the die. For example, because of variations in channel length, doping levels or other considerations, one section may require forward body bias, e.g., when a particular section has a maximum operating frequency F_{MAX} that is too slow for a particular application. In this case the central bias generator may generate a signal that forward biases the section, to thereby increase F_{MAX} to lie within a predetermined (e.g., optimal) range or match a predetermined value.

Other sections may require reverse body bias, e.g., when the standby leakage current I_{SB} of the section is too high. In this case the central bias generator may generate a signal that reverse biases the section, to thereby decrease I_{SB} to lie within a predetermined (e.g., optimal) range or match a predetermined value. In still other cases, the body bias signals may adjust a plurality of operating parameters to match predetermined ranges or values in each section, or even to apply a zero body bias if the application so warrants or if no within-die process variations exist for a given section.

One additional parameter that may be taken into consideration is robustness of the circuit (e.g., the tolerance of the circuit to noise). The body bias for each section may be chosen to effect a desired robustness of the circuit.

A controller according to the preferred embodiment of the present invention may therefore selectively and simultaneously apply different body biases (reverse, forward, or zero) to different sections of a die to thereby optimize die performance, power requirements, bin split, and/or cost considerations.

The selector 20 generates control signals for routing the body bias signals along pre-established conduction paths to the desired type(s) of transistors in the respective sections of the die. For example, the selector may output select signals to the central bias generator which causes bias signals S₁, S₂, . . . S_{N-1}, and S_{N} to be routed to the desired type(s) of transistors in sections 2₁, 2₂, . . . 2_{N-1}, and 2_{N} respectively. The selector may be constructed in a variety of ways to control routing of the bias signals. One non-limiting construction is discussed in greater detail below.

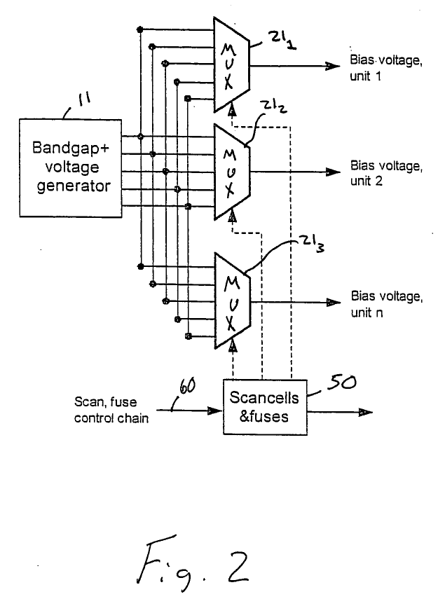

FIG. 2 shows how the central bias generator and selector may be constructed in accordance with one non-limiting embodiment of the invention. In this example, the central bias generator includes a bandgap voltage generator 11 which generates a plurality of predetermined bias signals from a reference signal (now shown) which is preferably process, voltage, and temperature-independent. The bias voltage, for example, may span a desired range of biases voltages in predetermined steps or increments, or alternatively may be set to specific values optimally selected to reduce or eliminate within-die process variations of each respective section of the die. An example of such a range includes a reverse body bias of 500 mV to a forward body bias of 500 mV. Other ranges may be used based on the requirements of a specific application, e.g., only zero body bias to forward body bias (or reverse body bias to zero body bias) may be used in order to realize a simpler yet still sophisticated solution.

The number of bias signals (and the increments therebetween) may be determined by a tradeoff between complexity and performance, however a bias resolution of 100 mV has been found to be sufficient for some applications. (A 500 mV reverse body bias to 500 mV forward body bias having a bias resolution of 100 mV will result in the generation of eleven bias voltages, each of which may be used to bias a respective section of the die). The bandgap generator may be formed, for example, from a resistive network or from complex active circuitry.

With reference to FIG. 2, the selector may include a plurality of multiplexers each receiving as inputs the bias signals output from the bandgap voltage generator. The number of multiplexers may be varied depending, for example, on the extent to which different body bias signals are required to drive the die sections. For instance, if half the sections require a first body bias signal and the other half require a second body bias signal, the selector may only be formed from two multiplexers, because only two of the signals output from bandgap generator are required to bias the entire die.

Alternatively, the number of multiplexers may equal the number of bias signals output from the bandgap generator or the number of sections on the die, and this may be so even when multiple sections of the die are driven by a same bias voltage. For illustrative purposes, three multiplexers 21₁-21₃ are shown in FIG. 2.

The selector may further include a control circuit 50 for generating the select signals for the multiplexers. The control circuit may take any one of a variety of forms and is preferably included on the die with the central bias generator. As shown in FIG. 2, the control circuit may be formed from scan cells and an array of fuses, the latter of which may be permanently or erasably programmed (e.g., in accordance with control signal 60) to control the routing of body bias signals from the central bias generator to respective ones of the die sections.

The scanning circuitry (comprising the scan cells) may be similar to the type used during a debug phase of a microprocessor testing operation. Unlike conventional testing operations, however, scanning circuitry 50 may be used to implement a die testing procedure in accordance with one or more embodiments of the present invention described in greater detail below.

Returning to FIG. 1, the controller also preferably includes local bias generators 3₁, 3₂, . . . 3_{N-1}, and 3_{N}, one in each section of the die. Each local bias generator translates a respective one of the body bias signals from generator 10 into a local body bias signal generated with reference to a local supply voltage (e.g., V_{CC} for PMOS bias or V_{SS} for NMOS bias) for that section. The local body bias generators preferably have sufficient strength to supply local bias voltages to all transistors (AMOS or NMOS) of the specific type(s) to be biased. Examples of local bias generators which of this type are disclosed, for example, in S. Narendra et al., 1.1 v 1 GHz Communications Router with On-Chip Bias in 150 nm CMOS, ISSCC 2002, and U.S. Pat. No. 6,784,722.

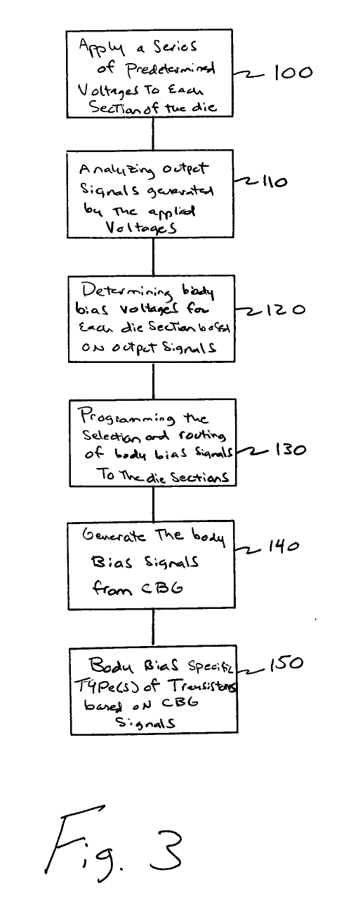

FIG. 3 shows functional blocks that may be included in a method for providing within-die bias of a semiconductor device in accordance with one embodiment of the present invention. The method initially includes a series of functional blocks to determine the voltages to be used in biasing respective sections of the die. In an initial block, a series of bias voltages are applied to each of the sections (Block 100), and then one or more output signals generated by the applied voltages are analyzed (Block 110). The applied voltages may be ones selected within a predetermined range of body bias voltages having a bias resolution such as previously discussed with reference to FIG. 2.

A bias voltage is determined for each section of the die based on the analysis of the output signals. (Block 120). During this analysis, it may be determined, for example, that one of the voltages overcomes process variations better than the others, e.g., one of the voltages may apply a transistor bias which causes the maximum operating frequency of a particular section to lie within a predetermined range or match a desired operating frequency better than the others. This voltage may therefore be determined for use in biasing that section.

Once the biasing voltages are determined, the circuit 20 that controls selection and routing of bias signals to the respective sections of the die is programmed. (Block 130). This may be accomplished, for example, by programming the fuses in the manner previously described. For maximum effectiveness, a correlation may be formed between one or more die parameters (e.g., F_{MAX} or I_{SB}) and optimum fuse values to be written. Once this programming block is finished, the die is ready for operation.

In operation, the biasing signals are generated by the central bias generator, for example, based on the select signals output from the control circuit. (Block 140). These signals are routed to respective sections of the die, where they are then used to bias a predetermined type of transistor (e.g., PMOS or NMOS) in each section.

The bias signals may be applied to bias the transistors in each section directly (e.g., as output from the central bias generator), or all or a portion of the die sections may include local bias generators which translate respective bias signals from generator 10 into local bias signals for driving the permissible type of transistors. (Block 150).

Because the bias signals have been selected to compensate for process variations in the sections of the die, an increase in overall performance of the die circuit may advantageously be realized. This compensation may involve, for example, controlling the maximum operating frequency and/or the standby leakage current to lie within certain ranges. This allows within-die process parameter variations to be compensated for, as well as die-to-die variations. Also, better control over the F_{MAX} and I_{SB} of each die section may be realized. This, in turn, translates into better bin split and, especially when applied to processor dies, increases the number of high-frequency parts. In this latter case, because more parts are moved into the highest-frequency bins, total revenue may be increased.

Referring to FIG. 1, in accordance with another embodiment of the present invention, the central bias generator generates body bias signals for different types of transistors on the die. For example, according to one scheme generator 10 may generate different body bias signals for only PMOS transistors in Unit 1 and for only NMOS transistors in Unit 2. According to other schemes, generator 10 may generate different body bias signals for PMOS and NMOS transistors within the same section of the die, different body bias signals for different PMOS transistors within the same or different sections of the die, and/or different body bias signals for different NMOS transistors within the same or different sections of the die. According to another scheme, only one type of transistor within the same or different sections of the die may receive body bias and other types may receive none at all.

One way these alternative schemes may be implemented is to fabricate the NMOS transistors using a triple-well process. This may be explained as follows. In an N-well fabrication process, PMOS transistors are fabricated in separate N-wells which isolate them from each other. Therefore, each PMOS transistor may receive its own body bias voltage while remaining isolated from other PMOS devices. However, the NMOS transistors are fabricated directly in the P-type substrate. If the substrate is biased (applying body bias to the NMOS transistors), all NMOS transistors receive the same body bias. Therefore, it may be difficult to provide different NMOS body bias voltages for different parts of the die.

To improve this capability, at least one embodiment of the present invention may use a triple-well process, in which NMOS transistors are fabricated in a P-well which is inside an N-well. This isolates the NMOS devices from each other and allows them to be separately biased.

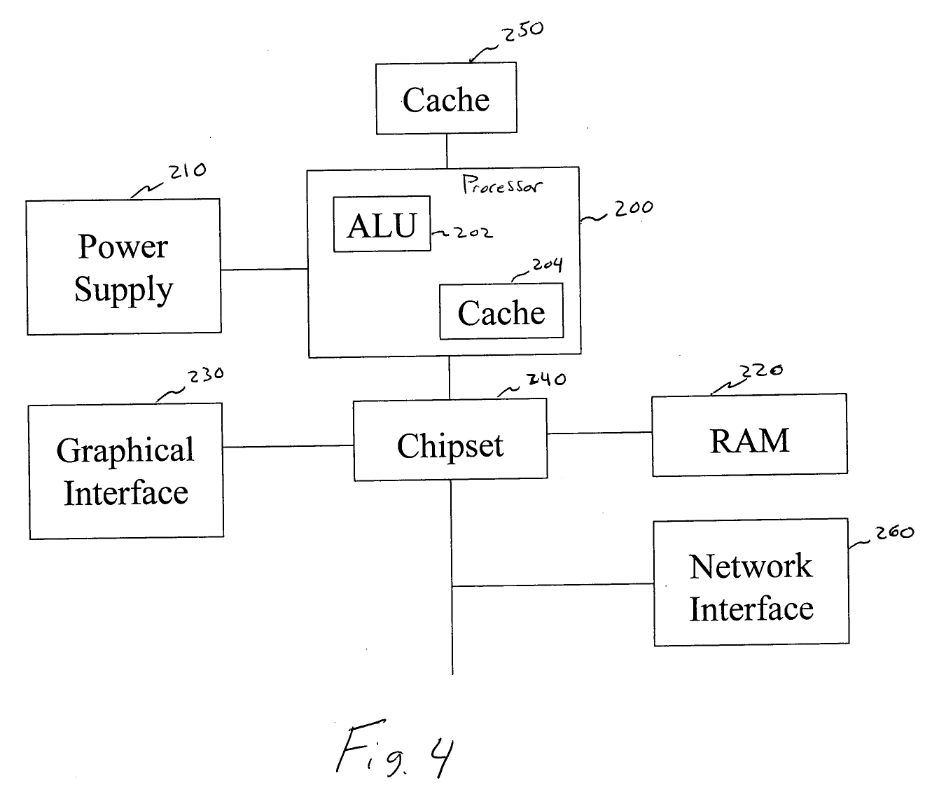

FIG. 4 shows system which includes a processor 200, a power supply 210, and a memory 220 which, for example, may be a random-access memory. The processor includes an arithmetic logic unit 202 and an internal cache 204. The system also preferably includes a graphical interface 230, a chipset 240, a cache 250, and a network interface 260. The processor may be a microprocessor or any other type of processor. The processor may be included on a chip die with all or any combination of the remaining features, or one or more of the remaining features may be electrically coupled to the microprocessor die through known connections and interfaces.

The system further includes a controller in accordance with any of the embodiments of the present invention described herein. The controller may be included on the same die as the processor, either apart from or incorporated within any one of the other circuits on the die. Further, each section of the die may encompass one or more of the processor, cache, power supply chipset, graphical interface, network interface, and/or memory, or different combinations thereof In operation, the controller generates signals for biasing specific types of transistors in each of the sections of the die. The controller may, for example, generate signals for applying forward body bias to the PMOS transistors in the processor and reverse body bias to the PMOS transistors in the chipset, to ensure that one or more operating parameters (e.g., F_{MAX} and I_{SB}) fall within predetermined ranges. Variations of this biasing scheme may be performed depending on, for example, the requirements of the specific application and/or the results of a chip scanning/testing operation.

In the foregoing embodiments, the central bias generator and selector are described as being located on the semiconductor die. In alternative embodiments, the selector may be an off-die component that generates select signals for controlling the routing of body bias signals to the different sections of the die.

Any reference in this specification to an “embodiment” means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Furthermore, for ease of understanding, certain functional blocks may have been delineated as separate blocks; however, these separately delineated blocks should not necessarily be construed as being in the order in which they are discussed or otherwise presented herein. For example, some blocks may be able to be performed in an alternative ordering, simultaneously, etc.

Although the present invention has been described herein with reference to a number of illustrative embodiments, it should be understood that numerous other modifications and embodiments can be devised by those skilled in the art that will fall within the spirit and scope of the principles of this invention. More particularly, reasonable variations and modifications are possible in the component parts and/or arrangements of the subject combination arrangement within the scope of the foregoing disclosure, the drawings and the appended claims without departing from the spirit of the invention. In addition to variations and modifications in the component parts and/or arrangements, alternative uses will also be apparent to those skilled in the art.

We claim:

1. A controller, comprising:
a signal generator to generate different first and second body bias signals; and
a selector to select the first body bias signal to control one or more first-type transistors in a first section of an IC die, and to select the second body bias signal to control one or more first-type transistors in a second section of the die, wherein the first-type transistors are the only transistor types controlled by the first and second body bias signals in the first and second sections of the die.

2. The controller of claim 1, wherein the first-type transistors are PMOS transistors.

3. The controller of claim 1, wherein the first-type transistors are NMOS transistors.

4. The controller of claim 1, wherein the first body bias signal controls an operating parameter of the first section and the second body bias signal controls an operating parameter of the second section.

5. The controller of claim 4, wherein the operating parameters are selected from the group consisting of operating frequency and standby leakage current.

6. The controller of claim 5, wherein the operating frequency is a maximum operating frequency for an associated one of the first and second sections.

7. The controller of claim 1, wherein the first body bias signal applies a forward body bias to the first section of the die, and the second body bias signal applies reverse body bias to the second section of the die.

8. The controller of claim 1, wherein the first body bias signal applies a forward body bias to the first section of the die, and the second body bias signal applies zero body bias to the second section of the die.

9. The controller of claim 1, wherein at least one of the signal generator and the selector are on the die.

10. The controller of claim 9, wherein the signal generator and the selector are on the die.

11. The controller of claim 1, further comprising:
first and second local signal generators,
wherein the first local signal generator converts the first body bias signal into a local body bias signal that controls the first-type transistors in the first section of the die, and the second local signal generator converts the second body bias signal into a local body bias signal that controls the first-type transistors in the second section of the die.

12. The controller of claim 11, wherein the first local signal generator converts the first body bias signal into said local body bias signal for the first section with reference to a supply voltage of the first section, and the second local signal generator converts the second body bias signal into said local body bias signal for the second section with reference to a supply voltage of the second section.

13. The controller of claim 1, wherein the selector includes:
a first multiplexer coupled to the first section of the die; and
a second multiplexer coupled to a second section of the die,
wherein the first multiplexer selects the first body bias signal for output to the first section based on a first select signal, and the second multiplexer selects the second body bias signal for output to the second section based on a second select signal.

14. The controller of claim 13, wherein the first and second select signals are determined by a scanning procedure.

15. The controller of claim 13, wherein the first and second select signals are generated by programmed fuses.

16. The controller of claim 1, wherein the first and second sections include units that perform different functions within the die.

17. The controller of claim 1, wherein the first and second sections correspond to different areas of the die.

18. A biasing method, comprising:
generating different first and second body bias signals; and
controlling one or more first-type transistors in a first section of an IC die based on the first body bias signal, and controlling one or more first-type transistors in a second section of the die based on the second body bias signal, wherein the first-type transistors are the only transistor types controlled by the first and second body bias signals in the first and second sections.

19. The method of claim 18, wherein the first-type transistors are PMOS transistors.

20. The method of claim 18, wherein the first-type transistors are NMOS transistors.

21. The method of claim 18, wherein the first body bias signal controls an operating parameter of the first section and the second body bias signal controls an operating parameter of the second section.

22. The method of claim 21, wherein the operating parameters are selected from the group consisting of an operating frequency and standby leakage current.

23. The method of claim 22, wherein the operating frequency is a maximum operating frequency of at least an associated one of the first and second sections.

24. The method of claim 18, wherein the first body bias signal applies a forward body bias to the first section, and the second body bias signal applies reverse body bias to the second section.

25. The method of claim 18, wherein the first body bias signal applies a forward body bias to the first section, and the second body bias signal applies zero body bias to the second section.

26. The method of claim 18, further comprising:
converting the first body bias signal into a local body bias signal to control the first-type transistors in the first section of the die; and
converting the second body bias signal into a local body bias signal to control the first-type transistors in the second section of the die.

27. The method of claim 26, wherein the first body bias signal is converted into said local body bias signal for the first section with reference to a supply voltage of the first section, and the second body bias signal is converted into said local body bias signal for the second section with reference to a supply voltage of the second section.

28. The method of claim 18, wherein the first and second sections include units that perform different functions within the die.

29. The method of claim 18, wherein the first and second sections correspond to different areas of the die.

30. A method for testing an IC die, comprising:
applying a series of bias voltages to each of a plurality of sections of an IC die; and
determining different ones of said voltages for body biasing first-type transistors in said sections based on results of the applied voltages, wherein the first-type transistors are the only transistor types to be biased by the different identified voltages.

31. The method of claim 30, wherein the first-type transistors are PMOS transistors.

32. The method of claim 30, wherein the first-type transistors are NMOS transistors.

33. The method of claim 30, further comprising:
programming a circuit on the die to route the different identified voltages to respective ones of the sections.

34. The method of claim 30, wherein programming includes:
programming fuses on the die to route the different identified voltages to respective ones of the sections.

35. A biasing method, comprising:
generating a plurality of different body bias signals;
applying one of the body bias signals to a first transistor on an IC die; and
applying another one of the body bias signals to a second transistor on the IC die.

36. The method of claim 35, wherein the first and second transistors are a same type of transistor.

37. The method of claim 35, wherein the first and second transistors are different types of transistors.

38. The method of claim 35, wherein the first and second transistors are located in different sections of the die.

39. A system on a die, comprising:
a first circuit section;
a second circuit section; and
a controller including:
(a) a signal generator to generate different first and second body bias signals; and
(b) a selector to select the first body bias signal to control one or more first-type transistors in a first section of an IC die, and to select the second body bias signal to control one or more first-type transistors in a second section of the die, wherein the first-type transistors are the only transistor types controlled by the first and second body bias signals in the first and second sections of the die.

40. The system of claim 35, wherein the first-type transistors are one of PMOS and NMOS transistors.
